(19) United States
(12) Patent Application Publication
(10) Pub. No.: US 2024/0224743 A1
(43) Pub. Date: Jul. 4, 2024

(54) Display Apparatus and Method For Fabricating Thereof

(71) Applicant: LG Display Co., Ltd., Seoul (KR)

(72) Inventors: Hyun Kim, Paju-si (KR); Da-Yeon Jeong, Paju-si (KR); Chul-Young Jang, Paju-si (KR); Sang-Mo Byun, Paju-si (KR)

(21) Appl. No.: 18/500,028

(22) Filed: Nov. 1, 2023

(30) Foreign Application Priority Data
Dec. 30, 2022 (KR) 10-2022-0190180

(51) Int. Cl. H10K 59/80; H10K 59/12; H10K 59/121; H10K 59/122; H10K 59/38

(52) U.S. Cl. CPC H10K 59/878; H10K 59/1201; H10K 59/1213; H10K 59/122; H10K 59/38; H10K 59/873; H10K 59/8792

(57) ABSTRACT

A display apparatus according to invention includes a substrate including a plurality of sub-pixels, a transistor disposed in each sub-pixel over the substrate, an organic light emitting device disposed in each sub-pixel over the substrate, a metal patterning layer over the organic light emitting device, and a reflective wall disposed in boundary area of the sub-pixels on the metal patterning layer.

### CROSS-REFERENCE TO RELATED APPLICATION

This application claims priority to and the benefit of Republic of Korea Patent Application No. 10-2022-0190180, filed on Dec. 30, 2022, the contents of which are incorporated herein by reference in its entirety.

### BACKGROUND

### 1. Technical field

This invention relates to a display apparatus and a method for fabrication thereof to prevent the mix of the color.

### 2. Discussion of the Related Art

Recently, a head mounted display apparatus (HMD) including an organic light emitting display apparatus has been developed. The head mounted display apparatus is a glasses type display apparatus of virtual reality (VR) that is worn in the form of glasses or a helmet and focuses on a short distance in front of the user's eyes. However, in the case of the head mounted display apparatus, since the image of the organic light emitting display apparatus is directly visible in front of the user's eyes, there is a problem of color mixing in which light is input from adjacent pixels.

### SUMMARY

An object of the invention is to provide a display apparatus capable of preventing color mixing and method of fabricating thereof.

In order to achieve the object, a display apparatus according to the invention includes a substrate including a plurality of sub-pixels, a transistor disposed in each sub-pixel over the substrate, an organic light emitting device disposed in each sub-pixel over the substrate, a metal patterning layer over the organic light emitting device, and a reflective wall disposed in boundary area of the sub-pixels on the metal patterning layer.

The metal patterning layer includes a first metal pattering layer formed of an organic material and a second metal pattering layer formed of the organic material, the second metal patterning layer being surface-reformed. The second metal patterning layer is surface-reformed by a laser. The reflective wall is disposed on the second metal patterning layer.

The reflective wall is formed of the metal having getter characteristics such as at least one material selected from the group consisting of Al, Ag, rare-earth metal, and Ti.

A height of the reflective wall may be proportional to the area of the organic light emitting device of the corresponding sub-pixel, and the height of the reflective wall may be proportional to the area of the color filter layer of the corresponding sub-pixel. A width of the reflective wall may be proportional to the width of the bank layer.

A method of fabrication the display apparatus comprising providing a substrate including a plurality of sub-pixels, forming a transistor in each sub-pixel over the substrate, forming an organic light emitting device in each sub-pixel over the substrate, forming a metal patterning layer over the organic light emitting device, surface-reforming the metal patterning layer in the boundary region of the plurality of sub-pixels to improve surface energy in the corresponding portion or adhesion to metal, and forming a reflective wall on the surface-reformed metal patterning layer by depositing the metal.

The surface-reforming the metal pattering layer may include irradiating ultraviolet rays to corresponding region.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a schematic block diagram of a display apparatus according to the invention.

FIG. 2 is the schematic block diagram of a sub pixel according to the invention.

FIG. 3 is a circuit diagram conceptually illustrating the sub pixel of an organic light emitting display apparatus according to the invention.

FIG. 4 is a schematic cross-sectional view of the display apparatus according to the first embodiment of the invention.

FIG. 5 is a plan view schematically showing a reflective wall of the display apparatus according to the first embodiment of the invention.

FIGS. 6A and 6B are cross-sectional views showing other structures of the display apparatus according to the first embodiment of the invention.

FIG. 7 is a cross-sectional view showing the structure of the display apparatus according to the first embodiment of the invention in detail.

FIGS. 8A to 8G are views showing a manufacturing method of the display apparatus according to the invention.

FIG. 9 is a cross-sectional view showing the structure of the display apparatus according to the second embodiment of the invention in detail.

FIG. 10 is a cross-sectional view showing the structure of the display apparatus according to the third embodiment of the invention in detail.

### DETAILED DESCRIPTION

Advantages and features of the present disclosure and methods for achieving them will be made clear from embodiments described in detail below with reference to the accompanying drawings. The present disclosure may, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains, and the present disclosure is defined only by the scope of the appended claims.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein. When terms such as “including,” “having,” “comprising,” and the like mentioned in this disclosure are used, other parts may be added unless the term “only” is used herein. When a component is expressed as being singular, being plural is included unless otherwise specified.

In analyzing a component, an error range is interpreted as being included even when there is no explicit description.

In describing a positional relationship, for example, when a positional relationship of two parts is described as being “on,” “above,” “below,” “next to,” or the like, unless “immediately” or “directly” is not used, one or more other parts may be located between the two parts.

In describing a temporal relationship, for example, when a temporal predecessor relationship is described as being “after,” “subsequent,” “next to,” “prior to,” or the like, unless “immediately” or “directly” is not used, cases that are not continuous may also be included.

Although the terms first, second, and the like are used to describe various components, these components are not substantially limited by these terms. These terms are used only to distinguish one component from another component. Therefore, a first component described below may substantially be a second component within the technical spirit of the present disclosure.

In describing the components of the invention, terms such as first, second, A, B, (a), (b), etc. may be used. These terms are only for distinguishing the elements from other elements, and the essence, order, or number of the elements are not limited by the terms. When it is described that a component is “connected” “coupled” or “connected” to another component, the component may be directly connected or connected to the other component, but indirectly without specifically stated It should be understood that other components may be “interposed” between each component that is connected or can be connected.

As used herein, the term “apparatus” may include a display apparatus such as a liquid crystal module (LCM) including a display panel and a driving unit for driving the display panel, and an organic light emitting display module (OLED module). Further, the term “apparatus” may further include a notebook computer, a television, a computer monitor, a vehicle electric apparatus including an apparatus for a vehicle or other type of vehicle, and a set electronic apparatus or a set apparatus such as a mobile electronic apparatus of a smart phone or an electronic pad, etc., which are a finished product (complete product or final product) including LCM and OLED module.

Accordingly, the apparatus in the invention may include the display apparatus itself such as the LCM, the OLED module, etc., and the application product including the LCM, the OLED module, or the like, or the set apparatus, which is the apparatus for end users.

Hereinafter, the disclosure will be described in detail with reference to the accompanying drawings.

This invention can be applied to the various display apparatus. For example, the display apparatus of this invention can be applied to various display apparatus such as an organic light emitting display apparatus, a liquid crystal display apparatus, an electrophoretic display apparatus, a quantum dot display apparatus, a micro-LED (Light Emitting Device) display apparatus, and a mini-LED display apparatus. However, in the following description, the organic light emitting display apparatus will be described as an example for convenience of explanation.

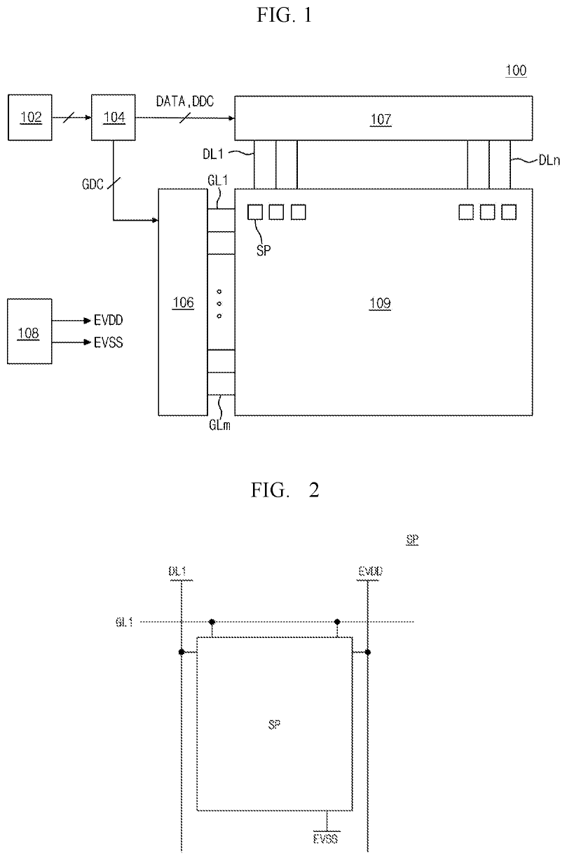

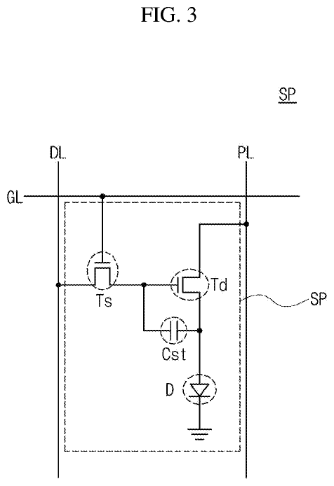

FIG. 1 is the schematic block diagram and FIG. 2 is the schematic block diagram of the sub-pixel of the organic light emitting display apparatus according to this invention.

As shown in FIG. 1, the organic light emitting display apparatus 100 includes an image processing unit 102, a timing controlling unit 104, a gate driving unit 106, a data driving unit 107, a power supplying unit 108, and a display panel 109.

The image processing unit 102 outputs an image data supplied from outside and a driving signal for driving various devices. For example, the driving signal from the image processing unit 102 can include a data enable signal, a vertical synchronizing signal, a horizontal synchronizing signal, and a clock signal.

The image data and the driving signal are supplied to the timing controlling unit 104 from the image processing unit 102. The timing controlling unit 104 writes and outputs gate timing controlling signal GDC for controlling the driving timing of the gate driving unit 106 and data timing controlling signal DDC for controlling the driving timing of the data driving unit 107 based on the driving signal from the image processing unit 102.

The gate driving unit 106 outputs the scan signal to the display panel 109 in response to the gate timing control signal GDC supplied from the timing controlling unit 104. The gate driving unit 106 outputs the scan signal through a plurality of gate lines GLI to GLm. In this case, the gate driving unit 106 may be formed in the form of an integrated circuit (IC), but is not limited thereto. The gate driving unit 106 includes various gate driving circuits, and the gate driving circuits may be directly formed on the substrate 110. In this case, the gate driving unit 106 may be a gate-in-panel (GIP).

The data driving unit 107 outputs the data voltage to the display panel 109 in response to the data timing control signal DDC input from the timing controlling unit 104. The data driving unit 107 samples and latches the digital data signal DATA supplied from the timing controlling unit 104 to convert it into the analog data voltage based on the gamma voltage. The data driving unit 107 outputs the data voltage through the plurality of data lines DL1 to DLn. In this case, the data driving unit107 may be mounted on the upper surface of the display panel 109 in the form of an integrated circuit (IC), but is not limited thereto.

The power supplying unit 108 outputs a high potential voltage VDD and a low potential voltage VSS etc. to supply these to the display panel 109. The high potential voltage VDD is supplied to the display panel 109 through the first power line EVDD and the low potential voltage VSS is supplied to the display panel 109 through the second power line EVSS. In this time, the voltage from the power supplying unit 108 are applied to the data driving unit 107 or the gate driving unit 106 to drive thereto.

The display panel 109 displays the image based on the data voltage from the data driving unit 107, the scan signal from the gate driving unit 106, and the power from the power supplying unit 108.

The display panel 109 includes a plurality of sub-pixels SP to display the image. The sub-pixel SP can include Red sub-pixel, Green sub-pixel, and Blue sub-pixel. Further, the sub-pixel SP can include White sub-pixel, the Red sub-pixel, the Green sub-pixel, and the Blue sub-pixel. The White sub-pixel, the Red sub-pixel, the Green sub-pixel, and the Blue sub-pixel may be formed in the same area or may be formed in different areas.

As shown in FIG. 2, one sub-pixel SP may be connected to the gate line GLI, the data line DL1, the first power line EVDD, and the second power line EVSS. The number of transistors, capacitors and the driving method of the sub-pixel SP are determined according to the circuit configuration.

FIG. 3 is the circuit diagram illustrating the sub-pixel SP of the organic light emitting display apparatus 100 according to the present invention.

As shown in FIG. 3, the organic light emitting display apparatus 100 according to the present invention includes the gate line GL, the data line DL, and the power line PL crossing each other for defining the sub-pixel SP. A switching thin film transistor Ts, a driving thin film transistor Td, a storage capacitor Cst, and an organic light emitting device D are disposed in the sub-pixel SP.

The switching thin film transistor Ts is connected to the gate line GL and the data line DL, and the driving thin film transistor Td and the storage capacitor Cst are connected between the switching thin film transistor Ts and the power line PL. The organic light emitting device D is connected to the driving thin film transistor Td.

In the organic light emitting display device having this structure, when the switching thin film transistor Ts is turned on according to the gate signal applied to the gate line GL, the data signal applied to the data line DL is applied to the gate electrode of the driving thin film transistor Td and one electrode of the storage capacitor Cst through the switching thin film transistor Ts.

The driving thin film transistor Td is turned on according to the data signal applied to the gate electrode. As a result, the current proportional to the data signal is supplied to the organic light emitting device D from the power line PL through the driving thin film transistor Td and then the organic light emitting device D emits light with a luminance proportional to the current flowing through the driving thin film transistor Td.

At this time, the storage capacitor Cst is charged with the voltage proportional to the data signal to keep the voltage of the gate electrode of the driving thin film transistor Td constant for one frame.

In the figure, only two thin film transistors Td and Ts and one capacitor Cst are provided, but the present invention is not limited thereto. Three or more thin film transistors and two or more capacitors may be provided in the present invention.

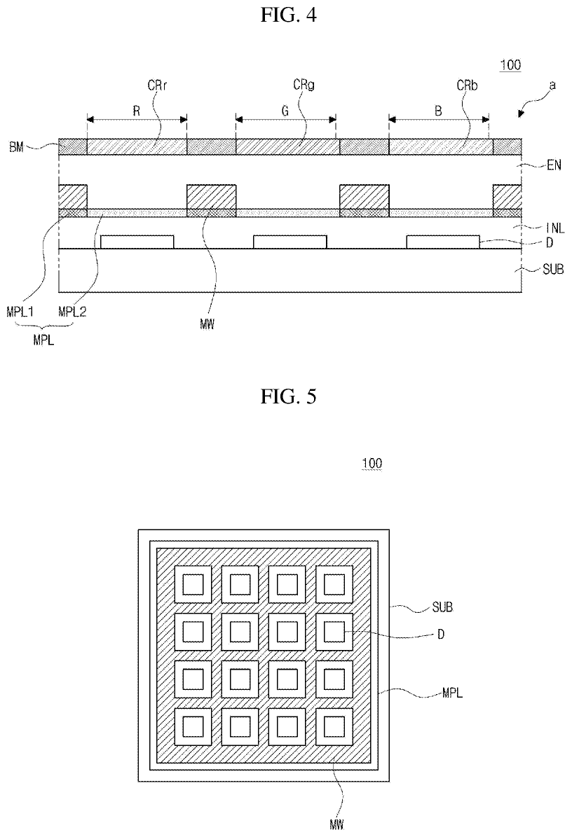

FIG. 4 is a plan view schematically illustrating the display apparatus 100 according to the first embodiment of this invention.

As shown in FIG. 4, the display apparatus according to this invention includes red sub-pixels R, green sub-pixels G, and blue sub-pixels B. An organic light emitting device D is disposed in each sub-pixel R, G, B on a substrate SUB.

Although not shown in the figures, a switching device such as a thin film transistor and various wires for transmitting various signals may be disposed in each of the sub-pixels R, G, and B. Although described in detail later, the organic light emitting device D includes a first electrode, a second electrode, and an organic layer disposed between the first electrode and the second electrode. As a voltage is applied to the first electrode and the second electrode, the organic layer is emitted to output light upward, thereby an image is displayed. In this case, the light may be white light.

An insulating layer INL is formed on the organic light emitting device D, and a reflective wall MW is disposed in a boundary region of the sub-pixels R, G, and B on the insulating layer INL. The reflective wall MW reflects the light from each of the sub-pixels R, G, and B to the corresponding sub-pixel instead of an adjacent sub-pixels, thereby preventing color mixing in the image. Further, the reflective wall MW can improve luminance by reflecting incident light back to the corresponding sub-pixel.

A metal patterning layer MPL is disposed between the insulating layer INL and the reflective wall MW. The metal patterning layer MPL is formed to pattern the reflective wall MW. The metal patterning layer MPL includes a first metal patterning layer MPL1 below the reflective wall MW and a second metal patterning layer MPL2 outside of the reflective wall MW. The second metal patterning layer MPL2 patterns the reflective wall MW by a self-aligning patterning method. Without a separate photolithography process, the deposited metal film is removed or the metal is not deposited on the second metal patterning layer MPL2 by interfacial characteristics with the second metal patterning layer MPL2.

The first metal patterning layer MPLI is formed of the same material as the second metal patterning layer MPL2, but the first metal patterning layer MPLI has characteristics different from those of the second metal patterning layer MPL2 by treating the surface of the first metal patterning layer MPL1. For example, the first metal patterning layer MPL1 can be irradiated with light such as ultraviolet rays to surface-reform the top surface of the first metal patterning layer MPLI to increase surface energy or improve adhesion to metal.

When the metal is deposited on the first metal patterning layer MPL1 and the second metal patterning layer MPL2, the metal desorption probability is very high on the surface of the second metal patterning layer MPL2 so that the nuclei of the deposited metal atoms are not generated. On the other hand, the nuclei of deposited metal atoms are generated on the surface of the surface-reformed first metal patterning layer MPLI to form the metal film.

Therefore, when the metal is deposited, the metal is deposited only on the upper surface of the surface-reformed first metal pattering layer MPL1, not on the upper surface of the second metal patterning layer MPL2, so that the reflective wall MW is formed only on the first metal pattering layer MPL1.

The metal patterning layer MPL may be formed of the organic material having low surface energy or low adhesion to metal.

As shown in FIG. 5, the metal patterning layer MPL is formed over the entire area of the substrate SUB, and the reflective wall MW is formed thereon. At this time, the metal patterning layers MPL are arranged in the horizontal and vertical directions so that the metal patterning layers MPL is formed in a matrix shape in the boundary regions of the sub-pixels R, G, and B. The organic light emitting device D is disposed in the sub-pixels R, G, and B between the metal patterning layers MPL.

The reflective wall MW may be formed in the same shape as the R, G, and B sub-pixels to surround the R, G, and B sub-pixels. For example, as shown in the figure, the reflective wall MW may be formed in the same rectangular shape as the rectangular R, G, and B sub-pixels. Further, the reflective wall MW may be formed in various shapes such as a circular shape, a rhombic shape, and a hexagonal shape.

Referring to FIG. 4, an encapsulation layer EN is formed over the metal patterning layer MPL on which the reflective wall MW is formed. The encapsulation layer EN may be made of the inorganic material or the organic material, or may be made of a plurality of layers made of the organic and inorganic materials.

A black matrix BM is disposed between the sub-pixels R, G, and B on the encapsulation layer EN, and color filter layers CRr, CRg, and CRb are disposed between the black matrices BM. The black matrix BM may be made of metal such as Cr or CrOx. Further, the black matrix BM may be made of black resin to block light from being output to regions between the sub-pixels R, G, and B. The color filter layers CRr, CRg, and CRb are made of color resin and display images by outputting the light having red, green, and blue colors.

As described above, in the display apparatus 100 according to the first embodiment of the invention, the reflective wall MW is formed in the boundary regions of the sub-pixels R, G, and B to reflect the light outputting to the adjacent sub-pixel into the corresponding sub-pixel, so that the image quality deterioration caused by mixing of the light formed adjacent sub-pixels can be prevented and the luminance can be improved.

In the invention, further, since the reflective wall MW is patterned using the metal patterning layer MPL, a separate photolithography process is not required. Therefore, the manufacturing process is simplified, and the eco-friendly can be realized since no harmful substances such as etching solution or developing solution are used.

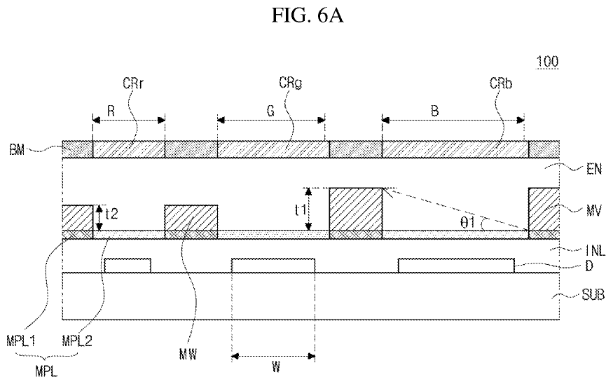

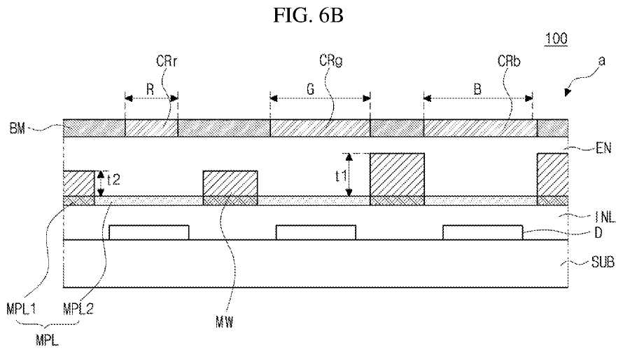

FIGS. 6A and 6B are views showing another structure of the display apparatus 100 according to the first embodiment of the invention.

As shown in FIG.6A, in this display apparatus, the areas of the organic light emitting device D of the R, G, B sub-pixels are different for each other. In this case, since the area of the organic light emitting device D means the light emitting area, the area of the organic light emitting device D may mean the area of the first electrode, for example, the anode electrode.

The area of the organic light emitting device D disposed in the B sub-pixel is the largest, the area of the organic light emitting device D disposed in the G sub-pixel is medium, and the area of the organic light emitting device D disposed in the R sub-pixel is the smallest. However, the area of the organic light emitting device D disposed in the R sub-pixel may be the largest, and the area of the organic light emitting device D disposed in the G sub-pixel may be medium, and the area of the organic light emitting device D disposed in the B sub-pixel may be the smallest. Further, area of two sub-pixels may be the same and only the area of one sub-pixel may be different.

The height t of the reflective wall MW may be proportional to the area w of the organic light emitting device D. That is, when the area w of the organic light emitting device D increases, the height of the reflective wall MW also increases. If the maximum angle of the light emitted from the organic light emitting device D and blocked by the reflective wall MW is θ, the reflective wall MW cannot block the light emitted by the emission angle θ when the area of the organic light emitting device D increases. Therefore, in the display apparatus 100, the height t1 of the reflective wall MW surrounding the sub-pixel (for example, sub-pixel B) in which the organic light emitting device D of the relatively large area w is disposed is greater than the height t2 of the reflective wall MW surrounding the sub-pixel (for example, R sub-pixel) in which the organic light emitting device D of the relatively small area w is disposed (t1>2), so that the light emitted to the adjacent sub-pixel is completely blocked and reflected to the corresponding sub-pixel.

As shown in FIG. 6B, in this display apparatus 100, the area of the color filter layers CRr, CRg, and CRb disposed respectively in the R, G, and B sub-pixels may be set differently. In this case, the area of the black matrix BM between the color filter layers CRr, CRg, and CRb is inversely proportional to the area a of the color filter layers CRr, CRg, and CRb.

For example, the area of the color filter layer CRr of the R sub-pixel may be the smallest, the area of the color filter layer CRg of the G sub-pixel may be medium, and the area of the color filter layer CRb of the B sub-pixel may be the largest. In this case, the area of the black matrix between the R sub-pixel and the G sub-pixel is larger than the area of the black matrix between the G sub-pixel and the B sub-pixel.

The height t of the reflective wall MW may be proportional to the area a of the color filter layer CR. That is, as the area of the color filter layer CR is decreased, the height of the reflective wall MW is also decreased. When the area a of the color filter layer CR is decreased and the area of the corresponding black matrix is increased, some of the light emitted from the adjacent sub-pixels is incident to the corresponding color filter layer CR and most of the light from the adjacent sub-pixels is incident to the black matrix. Accordingly, when the area a of the color filter layer CR is decreased, even if the height of the reflective wall MW is decreased, light emitted from the adjacent sub-pixel does not enter the corresponding color filter layer CR.

On the other hand, if the area a of the color filter layer CR is increased and the area a of the corresponding black matrix is decreased, some of the light emitted from the adjacent sub-pixels is incident to the black matrix, and most of the light emitted from the adjacent sub-pixels is entered to the corresponding color filter layer CR. Accordingly, in order to block light emitted from the adjacent sub-pixel from being incident to the corresponding color filter layer CR, the height of the reflective wall MW should be increased.

In this display apparatus 100 having this structure, therefore, the height tl of the reflective wall MW surrounding the sub-pixel (e.g., B sub-pixel) in which the color filter layer having the relatively large area is formed is larger than the height t2 of the reflective wall MW surrounding the sub-pixel (e.g., R sub-pixel) in which the color filter layer having the relatively small area is formed (t1>t2), so that the light emitted to the adjacent sub-pixel can be completely blocked and the blocked light may be reflected to the corresponding sub-pixel.

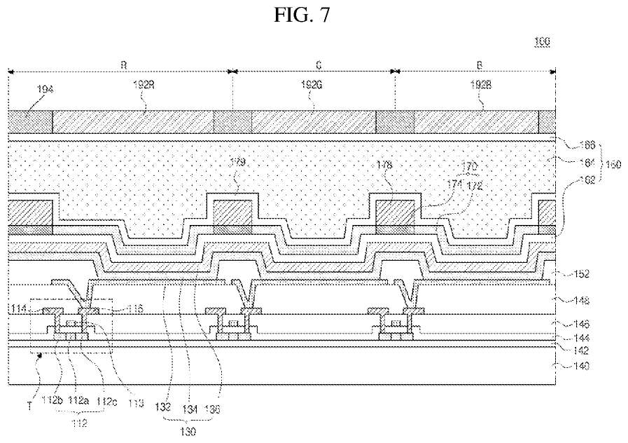

FIG. 7 is the cross-sectional view showing the structure of the display apparatus 100 according to the first embodiment of the invention in detail. Hereinafter, the display apparatus 100 according to the first embodiment of the invention will be described in more detail with reference thereto.

As shown in FIG. 7, the display apparatus 100 includes R, G, B sub-pixels.

As shown in FIG. 7, a first buffer layer 142 is formed on a substrate 140. The substrate 140 may be made of a hard material such as a glass or a plastic material, but not limited thereto. For example, the plastic material may include a polyimide, a polymethylmethacrylate, a polyethylene terephthalate, a Polyethersulfone, and a Polycarbonate.

When the substrate 140 is made of polyimide, the substrate 140 may be made of a plurality of polyimide layers, and an inorganic layer may be further disposed between the polyimide layers, but is not limited thereto.

The first buffer layer 142 may be formed in the entire area of the substrate 140 to enhance adhering force between the substrate 140 and the layers thereon. Further, the buffer layer 142 may block various types of defects, such as alkali components flowing out from the substrate 140. Further, the first buffer layer 142 may delay diffusion of moisture or oxygen penetrating into the substrate 140.

The first buffer layer 142 may be a single layer made of silicon oxide (SiOx) or silicon nitride (SiNx), or multi-layers thereof. When the buffer layer 142 is made of multiple layers, SiOx and SiNx may be alternately formed. The first buffer layer 142 may be omitted based on the type and material of the substrate 140, the structure and type of the thin film transistor, and the like.

A thin film transistor is formed in each of the R, G, B sub-pixels on the first buffer layer 142. For convenience of description, only the driving thin film transistor among various thin film transistors that may be disposed in the R, G, B sub-pixels is illustrated, but other thin film transistors such as switching thin film transistors may also be included. In the figure, the thin film transistor of a top gate structure is shown, but the thin film transistor is not limited to this structure and may be formed in other structures such as the thin film transistor of a bottom gate structure.

The thin film transistor includes a semiconductor pattern 112 disposed on the first buffer layer 142, a gate insulating layer 144 covering the semiconductor pattern 112, a gate electrode 113 on the gate insulating layer 144, an interlayer insulating layer 146 covering the gate electrode 113, and a source electrode 114 and a drain electrode 115 on the interlayer insulating layer 146.

The semiconductor pattern 112 may be made of a polycrystalline semiconductor. For example, the polycrystalline semiconductor may be made of low temperature poly silicon (LTPS) having high mobility, but is not limited thereto.

The semiconductor pattern 112 may be made of an oxide semiconductor. For example, semiconductor pattern 112 may be made of one of IGZO (Indium-gallium-zinc-oxide), IZO (Indium-zinc-oxide), IGTO (Indium-gallium-tin-oxide), and IGO (Indium-gallium-oxide), but is not limited thereto. The semiconductor pattern 112 includes a channel region 112a in a central region and a source region 112b and a drain region 112c which are doped layers at both sides of the channel region 112a.

The gate insulating layer 144 may be formed on the buffer layer 142 to cover the semiconductor layer 112. The gate insulating layer 144 may be composed of a single layer or multiple layers made of an inorganic material such as SiOx or SiNx, but is not limited thereto.

The interlayer insulating layer 146 may be formed on the gate insulating layer 144 cover the gate electrode 113. The interlayer insulating layer 146 may be made of the organic material such as photo-acryl, or the interlayer insulating layer 146 may formed of the single layer or the multiple layers made of the inorganic material such as SiOx or SiNx, but is not limited thereto. Further, the interlayer insulating layer 146 may be formed of the multi layers of the organic material layer and the inorganic material layer, but is not limited thereto.

The source electrode 114 and the drain electrode 115 are formed of the single layer or multi layers made of one or alloys of molybdenum (Mo), aluminum (Al), chromium (Cr), gold (Au), titanium (Ti), nickel (Ni), neodymium (Nd), and copper (Cu), but is not limited thereto. The source electrode 114 and the drain electrode 115 may be respectively contacted to the source region 112b and the drain region 112c of the semiconductor pattern 112 through contact holes formed in the gate insulating layer 144 and the interlayer insulating layer 146.

Not shown in figure, a bottom shield metal layer may be disposed on the substrate 140 under the semiconductor pattern 112. The bottom shield metal layer minimizes a backchannel phenomenon caused by charges trapped in the substrate 140 to prevent afterimages or deterioration of transistor performance. The bottom shield metal layer may be composed of the single layer or the multi layers made of titanium (Ti), molybdenum (Mo), or an alloy thereof, but is not limited thereto.

A planarization layer 148 is formed on the substrate 140 where the thin film transistor is disposed. The planarization layer 148 may be formed of the organic material such as photo acrylic. But it is not limited thereto. The planarization layer 148 may include a plurality of layers including the inorganic layer and the organic layer.

An organic light emitting device 130 is disposed in each of the R, G, and B sub-pixels on the planarization layer 148. The organic light emitting device 130 includes a first electrode 132, an organic layer 134, and a second electrode 136.

The first electrode 132 is disposed on the planarization layer 148 and electrically connected to the drain electrode 115 of the thin film transistor T through the contact hole formed in the planarization layer 148. The first electrode 132 may be formed of at least one of silver (Ag), aluminum (Al), gold (Au), molybdenum (Mo), tungsten (W), chromium (Cr), or an alloy thereof. The first electrode 132 is electrically connected to the drain electrode 115 of the thin film transistor to supply an image signal from the outside.

Further, the first electrode 132 may be formed of the transparent metal oxide layer such as indium tin oxide (ITO) or indium zinc oxide (IZO). At this time, the first electrode 132 may further include an opaque conductive material to function as a reflective electrode that reflects the incident light.

A bank layer 152 is formed at the boundary between the R, G, and B sub-pixels on the planarization layer 148. The bank layer 152 may be a kind of barrier rib defining R, G, and B sub-pixels.

The bank layer 152 is made of at least one material of the inorganic insulating material such as SiNx or SiOx, the organic insulating material such as BenzoCycloButene, acrylic resin, epoxy resin, phenolic resin, polyamide resin, or the photosensitizer including black pigment, but is not limited thereto.

The organic layer 134 is formed on the upper surface of the first electrode 132, the inclined surface of the bank layer 152, or the partial region of the upper surface of the bank layer 152. The organic layer 134 is formed in the R, G, and B sub pixels and may include an R-emitting layer for emitting red light, a G-emitting layer for emitting green light, and a B-emitting layer for emitting blue light. Further, the organic layer 134 may include a W-emitting layer for emitting white light. For example, the organic layer 134 may include an organic light emitting layer, an inorganic light emitting layer, a nano-sized material layer, a quantum dot layer, a micro-LED light emitting layer, or a mini-LED light emitting layer, but is not limited thereto.

The organic layer 134 may further include an electron injecting layer for injecting electrons into the light emitting layer, a hole injecting layer for injecting holes into the light emitting layer, an electron transporting layer for transporting the injected electrons to the light emitting layer, a hole transporting layer for transporting the injected holes to the light emitting layer, an electron blocking layer, and a hole blocking layer, but is not limited thereto.

The second electrode 136 is disposed on the organic layer 134 and may be formed of a half transparent conductive material. For example, the second electrode 136 may be formed of at least one of the alloys such as LiF/Al, CsF/Al, Mg:Ag, Ca/Ag, Ca:Ag, LiF/Mg:Ag, LiF/Ca/Ag, or LiF/Ca:Ag. Further, the second electrode 136 may be formed of the transparent metal oxide material such as indium tin oxide (ITO) or indium zinc oxide (IZO), but is not limited thereto.

Further, the organic light emitting device 130 may be formed in a tandem structure. The tandem structure may include a plurality of organic light emitting layers and a charge generating layer disposed between the organic light emitting layers. The charge generating layer is disposed to adjust the charge balance between the plurality of organic light emitting layers, and may be formed of a plurality of layers including a first charge generating layer and a second charge generating layer. The charge generating layer may include an N-type charge generating layer and a P-type charge generating layer. In this case, the charge generating layer may be formed of the organic layer doped with an alkali metal such as Li, Na, K, or Cs or an alkaline earth metal such as Mg, Sr, Ba, or Ra, but is not limited thereto.

An encapsulating layer 160 is formed on the organic light emitting device 130. When the organic light emitting device 130 is exposed to impurities such as moisture or oxygen, a pixel shrinkage phenomenon in which the light emitting area is reduced or the defect such as a dark spot in the light emitting area may occur. Further, moisture or oxygen penetrating into the organic light emitting device 130 oxidizes the metal electrode. The encapsulating layer 160 blocks impurities such as the oxygen and the moisture from the outside to prevent defects of the organic light emitting device 130 and various electrodes.

The encapsulating layer 160 may be formed of a first encapsulating layer 162, a second encapsulating layer 164, and a third encapsulating layer 166, but is not limited thereto. The encapsulating layer 160 may be formed of two layers including the organic layer and the inorganic layer or four or more layers.

The first encapsulating layer 162 and the third encapsulating layer 166 may be made of the inorganic material such as SiOx or SiNx, but are not limited thereto.

The metal patterning layer 170 is formed on the first encapsulation layer 162. The metal patterning layer 170 includes a first metal pattering layer 172 over the organic light emitting device 130 and a second metal patterning layer 174 over the bank layer 152 at the boundary of the R, G, and B sub-pixels.

As described in FIG. 4, the metal patterning layer 170 may be formed of the material having low surface energy or low adhesion to metal. For example, the metal patterning layer 170 may be formed of the transparent organic material having low surface energy or low adhesion to metal. At this time, the surface of the second metal patterning layer 174 is reformed by being irradiated with light such as ultraviolet rays. By the reformation of the surface of the metal patterning layer 170, the surface energy of the metal patterning layer 170 is increased and thus the adhesion property with metal is improved.

The reflective wall 178 is formed on the second metal patterning layer 174. When the metal layer is formed on the metal patterning layer 170 to form the reflective wall 178, the metal is not deposited on the upper surface of the first metal patterning layer 172 since the nuclear of the metal atoms is not generated on the upper surface of the first metal patterning layer 172 due to the low surface energy thereof. On the other hand, the nuclear of the metal atoms is generated on the upper surface of second first metal patterning layer 174 due to the high surface energy thereof. Accordingly, the reflective wall 178 is formed only on the second metal patterning layer 174.

The reflective wall 178 is formed of metal with good reflective property. In particular, the reflective wall 178 may be formed of the metal having getter characteristics. Therefore, since the impurities such as oxygen and moisture penetrating through the second encapsulation layer 164 are absorbed by the reflective wall 178, the penetration of impurities such as oxygen and moisture into the organic light emitting device 130 may be prevented. For example, the reflective wall 178 having such the getter characteristic may be formed of Al, Mg, a rare earth metals such as Ce, and Ti, but is not limited thereto. Further, the reflective wall 178 may be formed of the metal having no getter characteristics.

The reflective wall 178 may be formed at various heights. As described in FIGS. 6A and 6B, the height of the reflective wall 178 is proportional to the area of the organic light emitting device 130 or the area of the first electrode 132 of the organic light emitting device 130. That is, as the area of the organic light emitting device 130 of a specific sub-pixel or the first electrode 132 of the organic light emitting device 130 is increased, the height of the reflection wall 178 surrounding the corresponding sub-pixel is increased.

The height of the reflective wall 178 is proportional to the area of the color filter layers 192R, 192G, and 192B. The height of the reflective wall 178 is inversely proportional to the area of the black matrix 194. That is, as the area of the color filter layers 192R, 192G, and 192B of the specific sub-pixel is increased, the height of the reflection wall 178 surrounding the corresponding sub-pixel is increased.

When the bank layer 152 is formed of the black material containing black pigment, the width of the reflective wall 178 is proportional to the width of the bank layer 152. The light emitted from the organic light emitting device 130 is reflected not only from the side surface of the reflective wall 178 but also from the lower surface of the reflective wall 178. The light reflected from the lower surface of the reflective wall 178 is incident to adjacent sub-pixels, and color mixing may occur.

When the width of the bank layer 152 of the black material is wide, that is, when the area of the organic light emitting device 130 (or the first electrode 132) is small, most of the light reflected from the lower surface of the reflective wall 178 is absorbed by the bank layer 152. Therefore, even if the width of the reflective wall 178 is increased, light reflected from the lower surface of the reflective wall 178 is not incident to the adjacent sub-pixel.

On the other hand, when the width of the bank layer 152 of the black material is small, that is, when the area of the organic light emitting device 130 (or the first electrode 132) is large, most of the light reflected from the lower surface of the reflective wall 178 is not absorbed by the bank layer 152 and is incident to the adjacent sub-pixels. Therefore, the width of the reflective wall 178 is relatively small so that light reflected from the lower surface of the reflective wall 178 is not incident to the adjacent sub-pixels.

The second encapsulation layer 164 is formed on the first encapsulation layer 162 on which the reflective wall 178 is formed to cover completely the reflective wall 178. The second encapsulating layer 164 may be made of the organic insulating material such as acrylic resin, epoxy resin, polyimide, polyethylene, or silicon oxycarbon (SiOC), but is not limited thereto.

The third encapsulation layer 166 is formed on the second encapsulation layer 164. The third encapsulation layer 166 may be made of the inorganic material such as SiOx or SiNx, but is not limited thereto.

A second buffer layer 179 may be formed between the second encapsulation layer 164 and the reflective wall 178. The second buffer layer 179 improves adhesion between the second encapsulation layer 164 and the reflective wall 178 and blocks the impurities such as oxygen absorbed to the reflective wall 178 to the second encapsulation layer 164 to prevent the defects in the second encapsulation layer 164.

As shown in the figure, the second buffer layer 179 is deposited over the entire substrate 140 and thus formed on the side surface and the upper surface of the reflective wall 178 and on the upper surface of the first metal patterning layer 172. However, the second buffer layer 179 may not be formed on the upper surface of the first metal patterning layer 172 but may be formed only on the side surface and upper surface of the reflective wall 178 or may be omitted.

The second buffer layer 179 may be formed of the single layer of SiNx or SiOx or the multiple layers thereof. When the second buffer layer 179 is formed of the multiple layers, SiOx and SiNx may be alternately formed.

The R-color filter layer 192R, the G-color filter layer 192G, and the B-color filter layer 192B are respectively formed in the R, G, and B sub-pixels on the encapsulation layer 160, and the black matrix 194 is formed between the color filter layers 192R, 192G, and 192B.

As described above, in the display apparatus 100 according to the invention, the following effects can be obtained by the reflective wall 178.

First, in the display apparatus 100 according to the invention, the reflective wall 179 is formed at the boundary region of the sub-pixels R, G, and B to reflect the light outputting to the adjacent sub-pixel to the corresponding sub-pixel. Thus, it is possible to prevent the image quality defect due to color mixing caused by mixing light of the adjacent sub-pixels and to improve luminance.

Second, since the reflective wall 178 is patterned using the metal patterning layer 177 in the invention, a separate photolithography process is not required, thereby simplifying the manufacturing process and reducing manufacturing costs.

Third, since the separate photolithography process is not required, it is possible to prevent structural defects of the display apparatus from damage caused by the photolithography process.

Fourth, since the invention does not use harmful substances such as an etching solution or a developing solution, it is possible to realize eco-friendliness.

Fifth, in the invention, since the reflective wall is made of the metal having getter characteristics, the impurities such as oxygen and moisture penetrating from the outside are adsorbed to the reflective wall. Thus, it is possible to prevent defects due to penetration of the impurities.

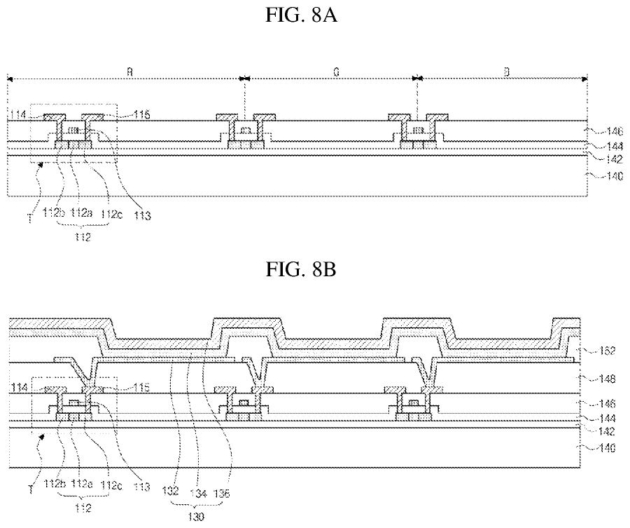

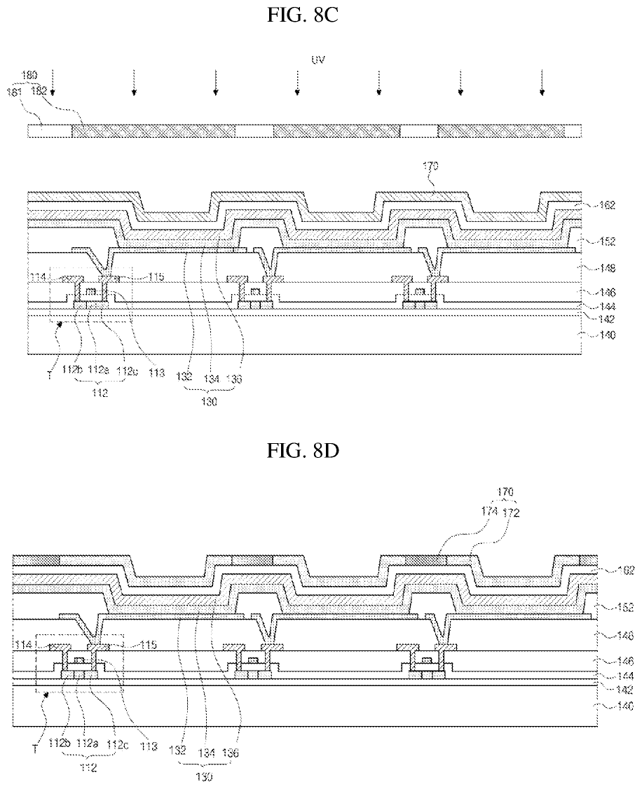

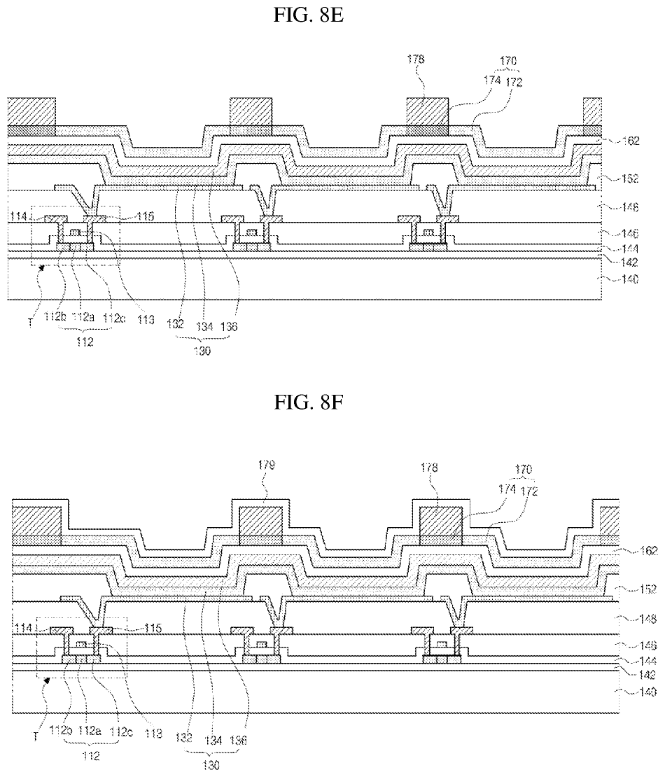

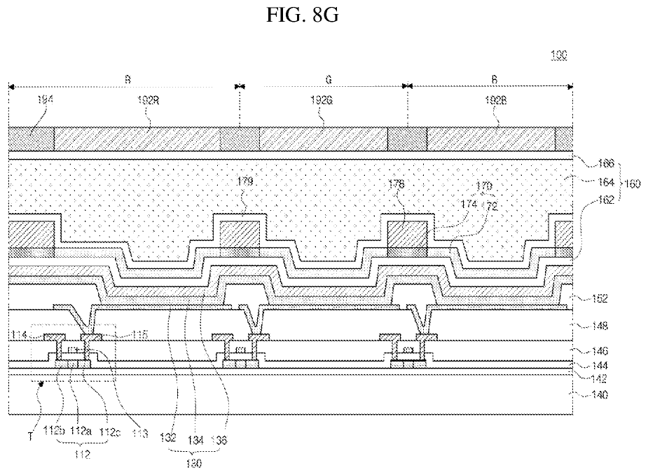

FIGS. 8A to 8G are views illustrating the manufacturing method of the display apparatus 100 according to the invention.

As shown in FIG. 8A, the buffer layer 142 including single layer made of silicon oxide (SiOx) or silicon nitride (SiNx), or multi-layers thereof is formed on the entire area of the substrate 140 which is made of the hard material such as the glass or the plastic material such as the plastic material may include a polyimide, a polymethylmethacrylate, a polyethylene terephthalate, a Polyethersulfone, and a Polycarbonate.

Thereafter, the poly-crystalline semiconductor material such as poly-silicon or the oxide semiconductor material such as etching IGZO (Indium-gallium-zinc-oxide), IZO (Indium-zinc-oxide), IGTO (Indium-gallium-tin-oxide), and IGO (Indium-gallium-oxide) is deposed and etched to form the semiconductor layer in each of the R, G, and B sub-pixels. Further, the impurities are doped into both sides of the semiconductor layer 112 to form the channel region 112a, the source region 112b, and the drain region 112c.

Subsequently, the gate insulating layer is formed 144 by depositing the inorganic material such as SiOx or SiNx, and then the metal such as molybdenum (Mo), aluminum (Al), chromium (Cr), gold (Au), titanium (Ti), nickel (Ni), Neodymium (Nd) and copper (Cu) are deposited by the sputtering method and etched by the wet etching method to form the gate electrode 113. Thereafter, the organic material such as photo acrylic material or the inorganic material such as SiNx or SiOx is deposited on the gate electrode 113 to form the interlayer insulating layer 146, and then the interlayer insulating layer146 over the source region 112b and the drain region 112c of the semiconductor layer 112 is dry-etched to form the contact holes therein.

Subsequently, the metal such as Cr, Mo, Ta, Cu, Ti, Al, or an Al alloy is deposited by the sputtering method and etched to form the source electrode 114 and the drain electrode 115 which are respectively ohmic-contacted to the source region 112b and the drain region 112c of the semiconductor layer 112 through the contact holes.

As shown in FIG. 8B, thereafter, the planarization layer 148 is formed by depositing the organic material such as photo-acryl on the source electrode 114 and the drain electrode 115, and then the planarization layer 148 on the drain electrode 115 is dry-etched to form the contact hole.

Thereafter, the metal or the metal oxide is deposited on the planarization layer 148 by the sputtering method and etched by the wet etching method to form the first electrode 132 electrically connected to the drain electrode 115 through the contact hole, and then at least one material of the inorganic insulating material such as SiNx or SiOx, the organic material such as BCB (BenzoCycloButene), acrylic resin, epoxy resin, phenolic resin, polyamide resin, and polyimide resin, and the photoresist including the black pigment is deposited on the planarization layer 148 and the first electrode 132 and dry-etched to form the bank layer 152.

Subsequently, the organic light emitting material is coated on the bank layer 152 and the first electrode 132, and the metal or the metal oxide is deposited to form the organic layer 134 and the second electrode 136 in order to form the organic light emitting element 130.

Subsequently, as shown in FIG. 8C, the inorganic material is deposited on the organic light emitting device 130 to form the first encapsulation layer 162.

Thereafter, the metal patterning layer 170 is formed by depositing the organic material having low surface energy or low adhesion to metal on the first encapsulation layer 162, and then a mask 180 is disposed thereon and the light such as ultraviolet ray is irradiated onto the metal patterning layer 170. At this time, the mask 180 includes a blocking portion 181 corresponding to the R, G, and B sub-pixels and a transmitting portion 182 corresponding to the boundary area of the R, G, and B sub-pixels, so that the ultraviolet rays are irradiated to the metal patterning layer 170 corresponding to the boundary regions of the R, G, and B sub-pixels.

As shown in FIG. 8D, as the ultraviolet rays are irradiated, the metal patterning layer 170 includes the first metal patterning layer 172 having original characteristics and the second metal patterning layer 174 in which the surface is surface-reformed by the ultraviolet rays or the adhesion characteristics to the metal is improved.

Subsequently, as shown in FIG. 8E, the metal having getter characteristics such as Al, Mg, the rare earth metal such as Ce, and Ti is deposited on the metal patterning layer by the sputtering method. in case, since the nuclei of metal atoms to be deposited are not generated on the top surface of the first metal patterning layer 172 having low surface energy or poor adhesion characteristics to metal, The metal layer is not formed on the upper surface of the first metal patterning layer 172.

On the contrary, since the nuclei of metal atoms are generated on the upper surface of the second metal patterning layer 174 having improved surface energy or improved adhesion characteristics to metal, the reflective wall 178 is formed on the upper surface of the second metal patterning layer 174.

Thereafter, as shown in FIG. 8F, the inorganic material such as SiNx or SiOx is deposited to form a second buffer layer 179 on the top and side surfaces of the reflective wall 178 and on the metal patterning layer 170.

Subsequently, as shown in FIG. 8G, the organic insulating material such as acrylic resin, epoxy resin, polyimide, polyethylene, or silicon oxycarbon (SiOC) is coated on the second buffer layer 179 to form the second encapsulation layer 164, and then the inorganic material such as SiNx or SiOx is deposited on the second encapsulation layer 164 to form the third encapsulation layer 166.

Thereafter, the black matrix 194 is formed in the boundary regions of the R, G, and B sub-pixels, and then color filter layers 192R, 192G, and 192B are formed between the black matrices.

As described above, in the display apparatus 100 according to the invention, the reflective wall 178 is formed by the self-assembly method without using photoresist, etchant, developer, etc., thereby simplifying the manufacturing process and reducing manufacturing cost.

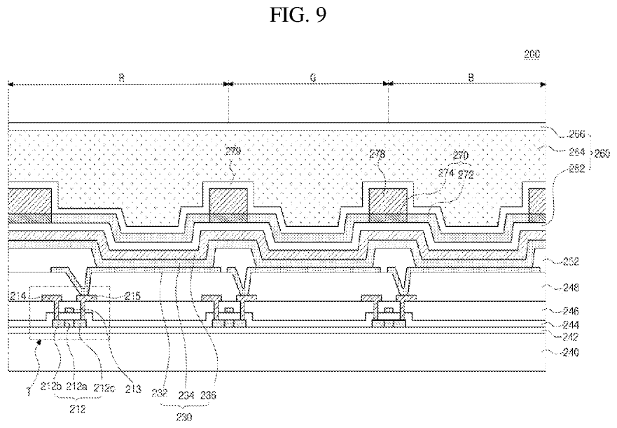

FIG. 9 is a cross-sectional view showing the structure of the display apparatus 200 according to the second embodiment of the invention. Descriptions of structures identical to those of the first embodiment will be simplified or omitted, and only other structures will be described in detail.

As shown in FIG. 9, in the display apparatus 200 of this embodiment, the red light, the green light, and the blue light are emitted from the organic light emitting device 230 disposed in the R, G, and B sub-pixels, respectively. Therefore, in the display apparatus 200 of this embodiment, unlike the first embodiment, the color filter layer and the black matrix are not formed on the encapsulation layer 260.

The reflective wall 278 is formed in a matrix shape in the boundary region of the R, G, and B sub-pixels to surround the R, G, and B sub-pixels. Since the metal patterning layer 270 is formed below the reflective wall 278, the reflective wall 278 may be formed by self-assembly patterning.

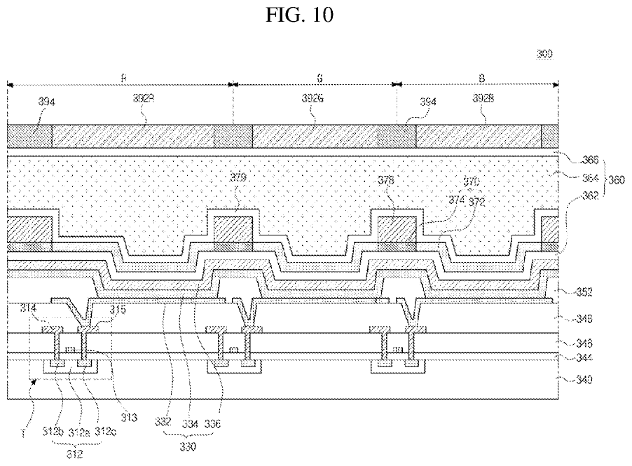

FIG. 10 is a cross-sectional view showing the structure of the display apparatus 300 according to the third embodiment of the invention. Descriptions of structures identical to those of the first embodiment will be simplified or omitted, and only other structures will be described in detail.

The display apparatus 300 of this embodiment is an OLEDoS (Organic Light Emitting Diode on Silicon) structure display apparatus 300 in which the active layer of the transistor is formed in a wafer substrate. In the OLEDoS structure organic light emitting display apparatus 300, since the active layer is formed in the wafer substrate to form the transistor, the single crystal transistor having excellent electrical mobility can be formed. Accordingly, it is possible to drastically reduce the size of the sub-pixel, and thus to manufacture a high-resolution display device.

Further, in the OLEDoS organic light emitting display apparatus 300, since transistors in the gate driver and data driver as well as transistors in the sub-pixels can be formed as single-crystal transistors, the response speed can be very fast.

The OLEDoS organic light emitting display apparatus 300 may be applied to various fields. For example, the OLEDoS organic light emitting display apparatus 300 may be applied to devices for a metaverse representing virtual worlds based on virtual reality (VR) and augmented reality (AR), which have recently been in the limelight.

As shown in FIG. 10, in the display apparatus 300 according to the third embodiment of the invention, transistors T are disposed in the wafer substrate 340 of each of the R, G, and B sub-pixels.

The transistor T includes the active region 312 disposed inside the wafer substrate 340, the gate insulating layer 344 formed on the upper surface of the wafer substrate 340, and the gate electrode disposed on the gate insulating layer 344, the interlayer insulating layer 346 on the gate electrode 313, and the source electrode 314 and the drain electrode 315 disposed on the interlayer insulating layer 346.

The wafer substrate 340 may be a single crystal semiconductor wafer formed by growing single crystal silicon (Si), but is not limited thereto and may be the wafer made of various semiconductor materials.

The active region 312 may be formed inside the wafer substrate 340. Some regions of the active region 312 of the wafer substrate 340 are doped with impurities, so that the active region 312 can include the central channel region 312a, which is not doped with impurities, and the source region 312b and the drain region 312c, which are doped by impurities, on both sides of the channel region 312a.

The bank layer 352 is formed in the boundary region between the R, G, and B sub-pixels above the transistor T, and the organic light emitting device 330 is formed between the bank layers 352.

The encapsulation layer 360 including the first encapsulation layer 362, the second encapsulation layer 364, and the third encapsulation layer 366 is formed on the organic light emitting device 330. The reflective wall 378 is formed in the boundary region of the R, G, and B sub-pixels on the first encapsulation layer 362. At this time, the metal patterning layer 370 is formed under the reflective wall 378, so that the reflective wall 378 can be formed by self-assembly patterning.

The black matrix 394 is formed in the boundary region of the R, G, and B sub-pixels on the encapsulation layer 360, and the color filter layers 392R, 392G, and 392B are formed on the R, G, and B sub-pixels between the black matrices 394.

In the display apparatus 300 of this embodiment, since the reflective wall 378 is formed in the boundary region between the R, G, and B sub-pixels, color mixing of the image due to light mixing with the adjacent R, G, and B sub-pixels can be prevented and the luminance is improved by the light reflection.

In particular, when the display apparatus is applied to the metaverse device based on virtual reality (VR) and augmented reality (AR), high pixel resolution (high Pixels Per Inch) is required. Therefore, in display apparatus for virtual reality (VR) and augmented reality (AR), since the distance between the sub-pixels is very small, color mixing by light mixed from adjacent R, G, and B sub-pixels frequently occurs.

However, in the display apparatus of this embodiment, the reflective wall 378 blocks light incident from adjacent R, G, and B sub-pixels, so that this display apparatus can be applied to the device for virtual reality (VR) and augmented reality (AR).

The above description and the accompanying drawings are merely illustrative of the technical spirit of the present invention, and those of ordinary skill in the art to which the present invention pertains can combine configurations within a range that does not depart from the essential characteristics of the present invention, various modifications or variations such as separation, substitution and alteration will be possible. Therefore, the embodiments disclosed in the present invention are not intended to limit the technical spirit of the present invention, but to explain, and the scope of the technical spirit of the present invention is not limited by these embodiments.

What is claimed is:

1. A display apparatus, comprising:
a substrate including a plurality of sub-pixels;
a transistor disposed in each sub-pixel over the substrate;
an organic light emitting device disposed in each sub-pixel over the substrate;
a metal patterning layer over the organic light emitting device; and
a reflective wall disposed in boundary area of the sub-pixels on the metal patterning layer.

2. The display apparatus of claim 1, wherein the metal patterning layer includes:
a first metal pattering layer formed of an organic material; and
a second metal pattering layer formed of the organic material, the second metal patterning layer being surface-reformed.

3. The display apparatus of claim 2, wherein the second metal patterning layer is surface-reformed by a laser.

4. The display apparatus of claim 2, wherein the reflective wall is disposed on the second metal patterning layer.

5. The display apparatus of claim 1, wherein the reflective wall is formed of metal having getter characteristics.

6. The display apparatus of claim 5, wherein the reflective wall is formed of at least one material selected from the group consisting of Al, Ag, rare-earth metal, and Ti.

7. The display apparatus of claim 1, further comprising:
a first encapsulation layer between the organic light emitting device and the metal patterning layer;
a buffer layer on the metal patterning layer to cover the reflective wall;
a second encapsulation layer on the buffer layer; and
a third encapsulation layer on the second encapsulation layer.

8. The display apparatus of claim 1, further comprising:
a plurality of color filter layers disposed respectively in each sub-pixel over the reflective wall; and
a black matrix between the color filter layers.

9. The display apparatus of claim 1, wherein a height of the reflective wall is proportional to an area of the organic light emitting device of a corresponding sub-pixel.

10. The display apparatus of claim 8, wherein the height of the reflective wall is proportional to an area of the color filter layer of the corresponding sub-pixel.

11. The display apparatus of claim 1, further comprising a bank layer made of black material in a boundary region of the plurality of sub-pixels,
wherein a width of the reflective wall is proportional to a width of the bank layer.

12. A method of fabrication of a display apparatus, comprising:
providing a substrate including a plurality of sub-pixels;
forming a transistor in each sub-pixel over the substrate;
forming an organic light emitting device in each sub-pixel over the substrate;
forming a metal patterning layer over the organic light emitting device;
surface-reforming the metal patterning layer in a boundary region of the plurality of sub-pixels to improve surface energy in a corresponding portion or adhesion to metal; and
forming a reflective wall on the surface-reformed metal patterning layer by depositing the metal.

13. The method of claim 12, wherein the surface-reforming the metal pattering layer includes irradiating ultraviolet rays to a corresponding region.

14. The method of claim 12, wherein the reflective wall is formed of the metal having getter characteristics.

15. The method of claim 14, wherein the reflective wall is formed of at least one material selected from the group consisting of Al, Ag, rare-earth metal, and Ti.
